(19) United States
(12) Patent Application Publication
(10) Pub. No.: US 2019/0346894 A1
(43) Pub. Date: Nov. 14, 2019

(54) FAN SIGNAL WIRELESS TRANSMISSION SYSTEM

(71) Applicant: ASIA VITAL COMPONENTS (CHINA) CO., LTD., Shenzhen (CN)

(72) Inventors: BOR-HAW CHANG, SHENZHEN (CN); SUNG-HSIEN SUN, SHENZHEN (CN); SUNG-WEI SUN, SHENZHEN (CN)

(21) Appl. No.: 15/978,182

(22) Filed: May 13, 2018

(51) Int. Cl. G06F 1/20; G06F 1/26; H05K 7/20; G08C 17/02

(52) U.S. Cl. CPC G06F 1/206; G08C 17/02; H05K 7/20209; G06F 1/26

(57) ABSTRACT

A fan signal wireless transmission system includes a system board, a first wireless signal transceiver module and at least one fan having a second wireless signal transceiver module. The first wireless signal transceiver module and the fan are mounted on the system board and connected to a power terminal and a ground terminal of the system board to obtain required power supply. The system board generates a wireless control signal that is wirelessly transmitted via the first wireless signal transceiver module to the fan, and wirelessly receives via the first wireless signal transceiver module a piece of fan information fed back by the fan to the system board. And, the fan wirelessly receives the wireless control signal and wirelessly outputs the fan information via the second wireless signal transceiver module.

### FIELD OF THE INVENTION

The present invention relates to a system having at least one fan, and more particularly, to a fan signal wireless transmission system.

### BACKGROUND OF THE INVENTION

Generally, a system board in a system space has a lot of electronic elements mounted thereon. These electronic elements produce a large quantity of heat when they operate. Therefore, fans are provided on the system board to facilitate quick removal of the heat produced by the electronic elements from the system space. The fans are electrically connected to the system board via flat cables, each of which includes a power line and a ground line, as well as a pulse width modulation (PWM) driving signal line and a fan rotational speed signal (FG) line or a temperature sensor line. On the other hand, the system board must also be provided with connectors having matching terminal holes for the flat cables of the fans to plug in. When there are multiple fans provided on the system board, more connectors must be correspondingly provided on the system board. Under this circumstance, the areas on the system board available for wiring will be reduced. Further, the large quantity of flat cables provided in the system space will result in disordered cable arrangement and interfere with the smooth flowing of air in the system space.

It is therefore tried by the inventor to develop a fan signal wireless transmission system that enables reduced number of flat cables in a system space thereof and increased wiring areas available on a system board thereof.

### SUMMARY OF THE INVENTION

A primary object of the present invention is to provide a fan signal wireless transmission system, which has a first wireless signal transceiver module and at least one fan mounted on and powered via a system board, so that the first wireless signal transceiver module can wirelessly output a signal generated by the system board to the at least one fan as well as wirelessly receive fan information fed back by the at least one fan to the system board.

Another object of the present invention is to provide a fan signal wireless transmission system, which enables reduced number of flat cables for individual fans and accordingly, enables air in the system space to smoothly flow without being interfered.

A further object of the present invention is to provide a fan signal wireless transmission system, a system board of which needs less connectors with matching terminal holes for fans mounted on the system board to connect thereto.

A still further object of the present invention is to provide a fan signal wireless transmission system, which includes a system board capable of wirelessly controlling at least one fan mounted on the system board and wirelessly receiving fan information fed back to the system board by the at least one fan.

A still further object of the present invention is to provide a fan signal wireless transmission system, which includes a first wireless signal transceiver module that can be detachably plugged onto or fixedly mounted on a system board for controlling at least one fan mounted on the system board.

A still further object of the present invention is to provide a fan signal wireless transmission system, which includes a system board capable of wirelessly communicating with at least one fan mounted on the system board using any one of the infrared, radio frequency (NF), Bluetooth, ZigBee, near-field communication (NFC), WiFi, radio-frequency identification (RFID) and 5G transmission protocols.

To achieve the above and other objects, the signal wireless transmission system according to a first embodiment of the present invention includes a system board, a first wireless signal transceiver module and at least one fan. The system board includes an output terminal, an input terminal, a power terminal and a ground terminal. The first wireless signal transceiver module is connected to the output terminal, the input terminal, the power terminal and the ground terminal of the system board to receive via the output terminal an output signal generated by the system board and to wirelessly transmit a wireless control signal according to the received output signal. The at least one fan includes a fan power terminal and a fan ground terminal connected to the power terminal and the ground terminal, respectively, of the system board, and a second wireless signal transceiver module for receiving the wireless control signal. The fan also wirelessly feeds back a piece of fan information via the second wireless signal transceiver module to the system board; and the fan information is wirelessly received by the first wireless signal transceiver module and transmitted to the system board via the input terminal of the system board.

To achieve the above and other objects, the signal wireless transmission system according to a second embodiment of the present invention includes a system board, a first wireless signal transceiver module and a plurality of fans. The system board includes an output terminal, an input terminal, a power terminal and a ground terminal. The first wireless signal transceiver module is connected to the output terminal, the input terminal, the power terminal and the ground terminal of the system board to receive via the output terminal an output signal generated by the system board and to wirelessly transmit a wireless control signal according to the received output signal. The fans are connected to a common second wireless signal transceiver module. Each of the fans includes a fan power terminal and a fan ground terminal connected to the power terminal and the ground terminal, respectively, of the system board. And the fans respectively wirelessly receive the wireless control signal via the common second wireless signal transceiver module, and respectively wirelessly feed back a piece of fan information to the system board via the common second wireless signal transceiver module. The first wireless signal transceiver module wirelessly receives the fan information from each of the fans and sends the received fan information to the system board via the input terminal of the system board.

According to the first and second embodiments of the present invention, the system board includes a board control unit, which generates the output signal.

According to the first and second embodiments of the present invention, the first wireless signal transceiver module includes a first processor and a first wireless transceiver element. The first wireless transceiver element wirelessly outputs the wireless control signal and wirelessly receives the fan information.

According to the first embodiment of the present invention, the fan includes a fan control unit and a fan motor connected to the fan control unit. The second wireless signal transceiver module is connected to the fan control unit and includes a second processor and a second wireless transceiver element connected to the second processor.

According to the first embodiment of the present invention, the first wireless signal transceiver module and the at least one fan are powered via the power terminal of the system board.

According to the second embodiment of the present invention, each of the fans includes a fan control unit and a fan motor connected to the fan control unit; and the common second wireless signal transceiver module is connected to each of the fan control units and includes a second processor and a second wireless transceiver element connected to the second processor.

According to the second embodiment of the present invention, the first wireless signal transceiver module and the fans are powered via the power terminal of the system board.

According to the first and second embodiments of the present invention, the system board and the first wireless signal transceiver module are two independent members. The system board has a first connector and the first wireless signal transceiver module has a second connector; and the first wireless signal transceiver module can be detachably mounted on the system board via connection of the second connector to the first connector.

According to the first and second embodiments of the present invention, the first wireless signal transceiver module can be otherwise fixedly mounted on the system board.

According to the first and second embodiments of the present invention, the first and the second wireless signal transceiver module can be any one of infrared modules, radio-frequency (RF) modules, Bluetooth modules, ZigBee modules, near-field communication (NFC) modules, WiFi modules, ultrasonic modules, radio-frequency identification (RFID) modules and 5G modules.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a perspective view of a system board for the fan signal wireless transmission system of the present invention;

FIG. 2 is a block diagram of the fan signal wireless transmission system according to a first embodiment of the present invention;

FIG. 3 is a block diagram of a second wireless signal transceiver module for the fan signal wireless transmission system according to the first embodiment of the present invention;

FIG. 4A is a block diagram showing the system board for the present invention includes a first connector;

FIG. 4B is a block diagram showing a first wireless signal transceiver module for the present invention includes a second connector;

FIG. 5 is a block diagram showing the system board for the first embodiment of the present invention has a plurality of fans provided thereon;

FIG. 6A is a block diagram of the fan signal wireless transmission system according to a second embodiment of the present invention; and

FIG. 6B is a block diagram of a fan for the fan signal wireless transmission system according to the second embodiment of the present invention.

### DETAILED DESCRIPTION OF THE PREFERRED EMBODIMENTS

The present invention will now be described with some preferred embodiments thereof and by referring to the accompanying drawings. For the purpose of easy to understand, elements that are the same in the preferred embodiments are denoted by the same reference numerals.

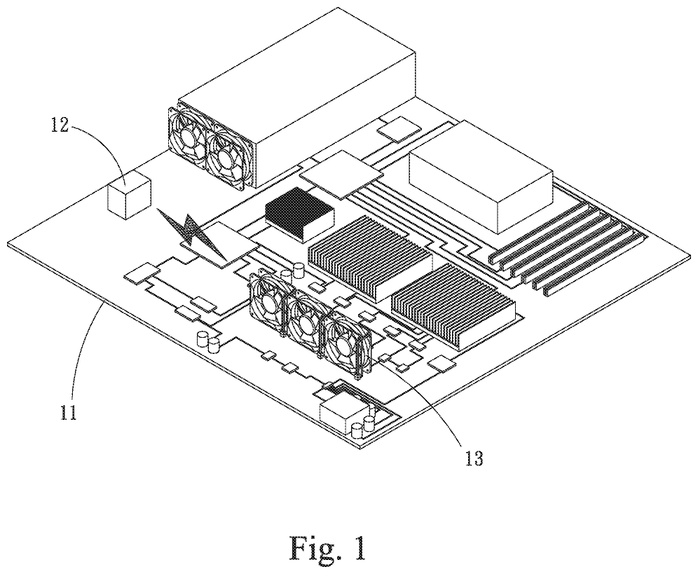

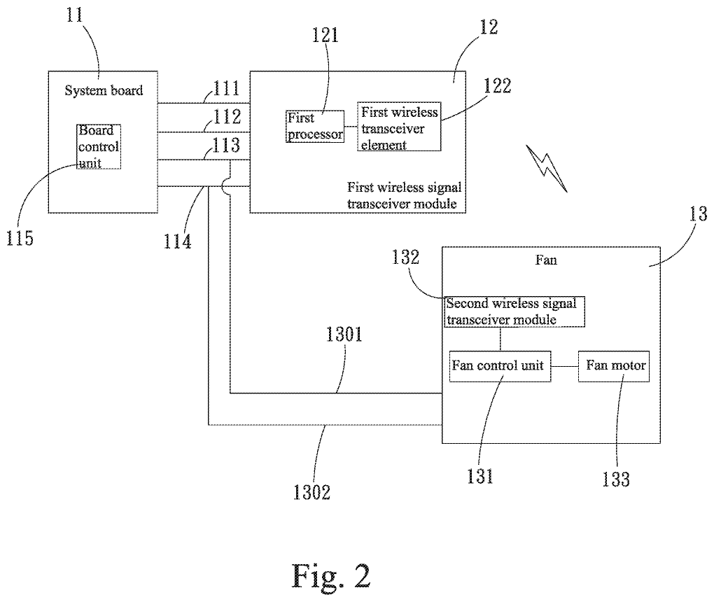

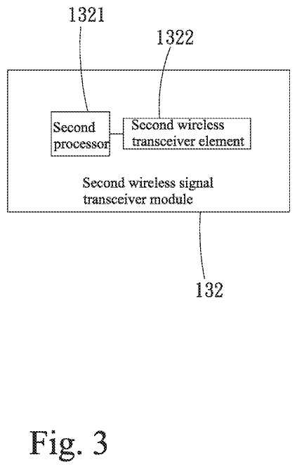

Please refer to FIG. 1 that is a perspective view of a system board 11 for a fan signal wireless transmission system of the present invention; to FIG. 2 that is a block diagram of the fan signal wireless transmission system according to a first embodiment of the present invention; and to FIG. 3 that is a block diagram of a second wireless signal transceiver module 132 for the fan signal wireless transmission system according to the first embodiment of the present invention. As shown, in the first embodiment of the present invention, there is included a system board 11, on which a first wireless signal transceiver module 12 and at least one fan 13 are mounted. The system board 11 includes an output terminal 111, an input terminal 112, a power terminal 113 and a ground terminal 114. The first wireless signal transceiver module 12 is connected to the output terminal 111, the input terminal 112, the power terminal 113 and the ground terminal 114 of the system board 11. The at least one fan 13 is connected to the power terminal 113 and the ground terminal 114 of the system board 11. And, the first wireless signal transceiver module 12 and the at least one fan 13 are powered via the power terminal 113 of the system board 11.

The system board 11 further includes a board control unit 115 for generating an output signal, which is output from the output terminal 111 to the first wireless signal transceiver module 12. The output signal can be, for example, a pulse width modulation (PWM) driving signal or a rotational speed regulating signal.

The first wireless signal transceiver module 12 includes a first processor 121 and a first wireless transceiver element 122. When the first wireless signal transceiver module 12 receives the output signal via the output terminal 111 of the system board 11, the first processor 121 wirelessly outputs a wireless control signal via the first wireless signal transceiver element 122. The wireless control signal is the PWM driving signal or the rotational speed regulating signal.

The fan 13 includes a fan power terminal 1301 and a fan ground terminal 1302, which are connected to the power terminal 113 and the ground terminal 114, respectively, of the system board 11 to obtain required power supply. The fan 13 also includes a fan control unit 131, which is connected to a second wireless signal transceiver module 132 and a fan motor 133 for receiving the wireless control signal via the second wireless signal transceiver module 132, so as to control the fan motor 133 to operate according to the received wireless control signal. In the case the received wireless control signal is the PWM driving signal, the fan control unit 131 controls the fan motor 133 to operate. On the other hand, in the case the received wireless control signal is the rotational speed regulating signal, the fan control unit 131 regulates the rotational speed of the fan motor 133.

The fan 13 can also wirelessly feed back a piece of fan information to the first wireless signal transceiver 12 via the second wireless signal transceiver module 132. The fan information can be, for example, a fan rotational speed signal (FG) or a fan failure signal, and is generated by the fan control unit 131 and sent to the first wireless signal transceiver 12 via the second wireless signal transceiver module 132. As can be seen in FIG. 3, the second wireless signal transceiver module 132 includes a second processor 1321 connected to a second wireless transceiver element 1322. The second wireless transceiver element 1322 receives the wireless control signal and sends the same to the second processor 1321. Further, the second processor 1321 generates the fan information, which is wirelessly transmitted to the first wireless signal transceiver module 12 via the second wireless transceiver element 1322.

When the first wireless transceiver element 122 of the first wireless signal transceiver module 12 wirelessly receives the fan information, the first processor 121 of the first wireless signal transceiver module 12 sends the received fan information to the system board 11. And, the board control unit 115 of the system board 11 receives the fan information via the input terminal 112 to obtain a current state of the fan 13.

Please refer to the following illustrative example for a better understanding of the operation relation between the system board 11 and the first wireless signal transceiver module 12 and the fan 13.

To drive the fan 13 to operate, the system board 11 first wirelessly transmits a PWM driving signal via the first wireless signal transceiver module 12, and the PWM driving signal is wirelessly received by the second wireless signal transceiver module 132 of the fan 13. Then, the fan control unit 131 receives the PWM driving signal from the second wireless signal transceiver module 132 and drives the fan motor 133 to operate according to the received PWM driving signal. When the fan motor 133 starts operating, the fan control unit 131 generates a fan rotational speed signal (FG) according to the rotational speed of the fan motor 133, and the fan rotational speed signal is wirelessly transmitted via the second wireless signal transceiver module 132 to the first wireless signal transceiver module 12. The first processor 121 of the first wireless signal transceiver module 12 receives the fan rotational speed signal (FG) via the first wireless transceiver element 122 and sends the received fan rotational speed signal to the system board 11. And, the board control unit 115 of the system board 11 receives the fan rotational speed signal via the input terminal 112 to thereby obtain the operating state of the fan 13.

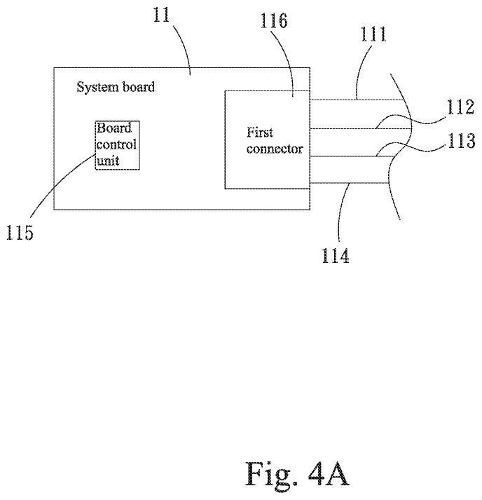

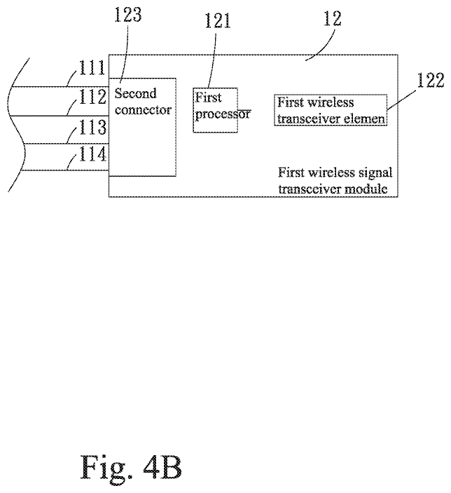

Please refer to FIGS. 4A and 4B, which are block diagrams showing the system board 11 having a first connector 116 and the first wireless signal transceiver module 12 having a second connector 123, respectively. As shown, in the first embodiment of the present invention, the system board 11 and the first wireless signal transceiver module 12 are two independent members, and are detachably connected to each other via connectors, namely, a first connector 116, such as a male terminal, provided on the system board 11 and a second connector 123, such as a female terminal, provided on the first wireless signal transceiver module 12. Therefore, the first wireless signal transceiver module 12 can be movably plugged onto the system board 11 or unplugged from the system board 11. According to an alternative embodiment, it is also possible for the first wireless signal transceiver module 12 to be directly fixedly mounted on the system board 11 by soldering, for example.

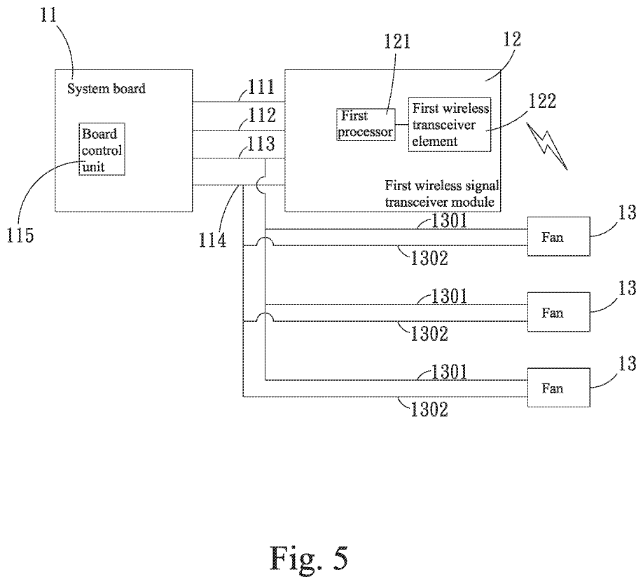

Please refer to FIG. 5, which is a block diagram showing the system board 11 for the present invention can also have a plurality of fans 13 provided thereon. In this case, each of the fans 13 has a fan power terminal 1301 and a fan ground terminal 1302 connected to the power terminal 113 and the ground terminal 114, respectively, of the system board 11 to obtain required power supply; the system board 11 transmits via the first wireless signal transceiver module 12 a wireless control signal to each of the fans 13; each of the fans 13 wirelessly feeds back a piece of fan information to the system board 11 via its own second wireless signal transceiver module 132; and the system board 11 receives via the first wireless signal transceiver module 12 the fan information from each of the fans 13 to obtain the operating state of each fan 13.

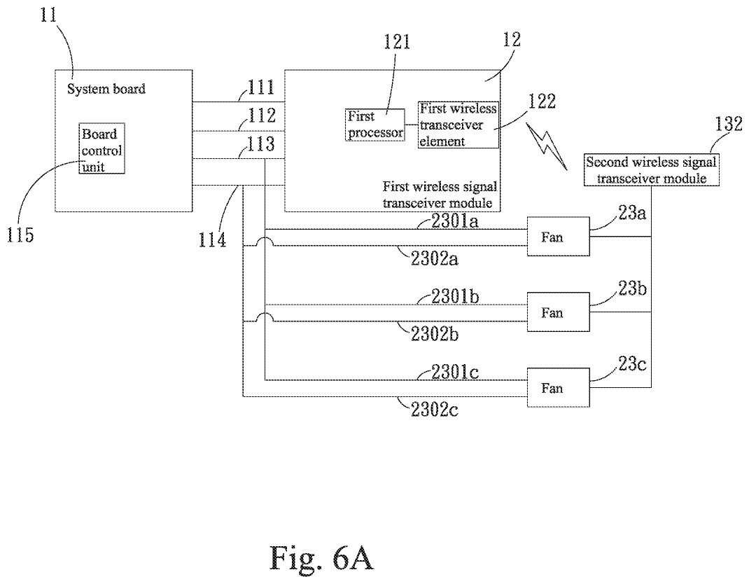

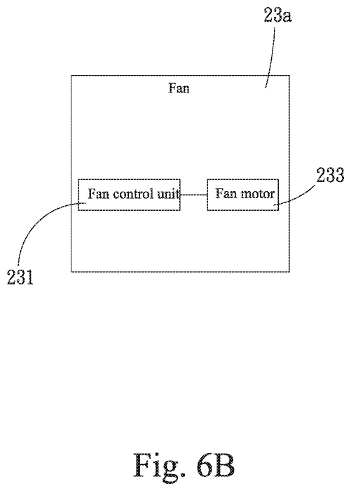

Please refer to FIG. 6A, which is a block diagram of the fan signal wireless transmission system according to a second embodiment of the present invention. The second embodiment is different from the first one in that, in the second embodiment, the system board 11 has a plurality of fans 23a, 23b, 23c provided thereon, which respectively have a fan power terminal 2301a, 2301b, 2301c and a fan ground terminal 2302a, 2302b, 2302c connected to the power terminal 113 and the ground terminal 114, respectively, of the system board 11 but have a common second wireless signal transceiver module 132. That is, the fans 23a, 23b, 23c wirelessly receive via the common second wireless signal transceiver module 132 a wireless control signal transmitted to each of them by the first wireless signal transceiver module 12, and wirelessly feed back their respective fan information to the first wireless signal transceiver module 12 via the common second wireless signal transceiver module 132. After wirelessly receiving the fan information of each of the fans 23a, 23b, 23c, the first wireless signal transceiver module 12 sends the received fan information to the system board 11 via the input terminal 112 of the system board 11.

FIG. 6B is a block diagram of the fan 23a. As shown, the fan 23a includes a fan control unit 231 and a fan motor 233. Since the fan 23b, 23c are structurally identical to the fan 23a, they are not repeatedly described herein. The common second wireless signal transceiver module 132 is electrically connected to the fan control unit 231 of each of the fans 23a, 23b, 23c.

It is noted the first wireless signal transceiver module 12 and the second wireless signal transceiver module/modules 132 in each of the above embodiments are both infrared modules, radio-frequency (RF) modules, Bluetooth modules, ZigBee modules, near-field communication (NFC) modules, WiFi modules, 5G modules, ultrasonic modules or radio-frequency identification (RFID) modules. When the first and second wireless signal transceiver modules 12, 132 are infrared modules, they transmit or receive infrared signals to or from one another; when the first and second wireless signal transceiver modules 12, 132 are RF modules, they transmit or receive RF signals to or from one another; when the first and second wireless signal transceiver modules 12, 132 are Bluetooth modules, they transmit or receive Bluetooth signals to or from one another; when the first and second wireless signal transceiver modules 12, 132 are ZigBee modules, they transmit or receive ZigBee signals to or from one another; when the first and second wireless signal transceiver modules 12, 132 are NFC modules, they transmit or receive NFC signals to or from one another; when the first and second wireless signal transceiver modules 12, 132 are WiFi modules, they transmit or receive WiFi signals to or from one another; when the first and second wireless signal transceiver modules 12, 132 are 5G modules, they transmit or receive 5G signals to or from one another; when the first and second wireless signal transceiver modules 12, 132 are ultrasonic modules, they transmit or receive ultrasonic signals to or from one another; or when the first and second wireless signal transceiver modules 12, 132 are RFID modules, they transmit or receive RFID signals to or from one another.

In summary, according to the embodiments of the present invention, the first wireless signal transceiver module 12 and the at least one fan 13, 23a, 23b, 23c are mounted on and powered via the system board 11; and the system board 11 generates the control signal, which is wirelessly output to the at least one fan 13, 23a, 23b, 23c via the first wireless signal transceiver module 12, and wirelessly receives via the first wireless signal transceiver module 12 the fan information fed back thereto by the at least one fan. Further, since the at least one fan 13, 23a, 23b, 23c is connected at the fan power terminal 1301, 2301a, 2301b, 2301c and the fan ground terminal 1302, 2302a, 2302b, 2302c to the power terminal 113 and the ground terminal 114, respectively, of the system board 11, it is able to omit the fan driving lines and the fan rotational speed feedback lines that are required in the conventional fans for connecting the fans to the system board. Therefore, in the present invention, the number of flat cables for the at least one fan 13, 23a, 23b, 23c is reduced. As a result, air in the system space, such as in the computer chassis, can flow smoothly without being interfered. Further, the number of connectors with matching terminal holes provided on the system board 11 for connecting to the fans is also reduced, enabling advantageous reduction of the volume of the connectors and increased circuit wiring areas available on the system board 11.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A fan signal wireless transmission system, comprising:
a system board including an output terminal, an input terminal, a power terminal and a ground terminal;
a first wireless signal transceiver module being connected to the output terminal, the input terminal, the power terminal and the ground terminal of the system board to receive via the output terminal an output signal generated by the system board and to wirelessly transmit a wireless control signal according to the received output signal; and
at least one fan including a fan power terminal and a fan ground terminal connected to the power terminal and the ground terminal, respectively, of the system board, and a second wireless signal transceiver module for receiving the wireless control signal; the fan wirelessly feeding back a piece of fan information via the second wireless signal transceiver module to the system board; and the fan information being wirelessly received by the first wireless signal transceiver module and transmitted to the system board via the input terminal of the system board.

2. The fan signal wireless transmission system as claimed in claim 1, wherein the system board includes a board control unit, which generates the output signal.

3. The fan signal wireless transmission system as claimed in claim 1, wherein the first wireless signal transceiver module includes a first processor and a first wireless transceiver element; and the first wireless transceiver element wirelessly outputting the wireless control signal and wirelessly receiving the fan information.

4. The fan signal wireless transmission system as claimed in claim 1, wherein the fan includes a fan control unit and a fan motor connected to the fan control unit; and the second wireless signal transceiver module being connected to the fan control unit and including a second processor and a second wireless transceiver element connected to the second processor.

5. The fan signal wireless transmission system as claimed in claim 1, wherein the first wireless signal transceiver module and the at least one fan are powered via the power terminal of the system board.

6. The fan signal wireless transmission system as claimed in claim 1, wherein the system board and the first wireless signal transceiver module are two independent members, the system board has a first connector, and the first wireless signal transceiver module has a second connector; and the first wireless signal transceiver module being detachably mounted on the system board through connection of the second connector to the first connector.

7. The fan signal wireless transmission system as claimed in claim 1, wherein the first wireless signal transceiver module is fixedly mounted on the system board.

8. The fan signal wireless transmission system as claimed in claim 1, wherein the first and the second wireless signal transceiver module are selected from the group consisting of infrared modules, radio-frequency (RF) modules, Bluetooth modules, ZigBee modules, near-field communication (NFC) modules, WiFi modules, ultrasonic modules, radio-frequency identification (RFID) modules and 5G modules.

9. A fan signal wireless transmission system, comprising:
a system board including an output terminal, an input terminal, a power terminal and a ground terminal;
a first wireless signal transceiver module being connected to the output terminal, the input terminal, the power terminal and the ground terminal of the system board to receive via the output terminal an output signal generated by the system board and to wirelessly transmit a wireless control signal according to the received output signal; and
a plurality of fans being connected to a common second wireless signal transceiver module; each of the fans including a fan power terminal and a fan ground terminal connected to the power terminal and the ground terminal, respectively, of the system board; and the fans respectively wirelessly receiving the wireless control signal via the common second wireless signal transceiver module, and respectively wirelessly feeding back a piece of fan information to the system board via the common second wireless signal transceiver module; and
the first wireless signal transceiver module wirelessly receiving the fan information from each of the fans and sending the received fan information to the system board via the input terminal of the system board.

10. The fan signal wireless transmission system as claimed in claim 9, wherein the system board includes a board control unit, which generates the output signal.

11. The fan signal wireless transmission system as claimed in claim 9, wherein the first wireless signal transceiver module includes a first processor and a first wireless transceiver element; and the first wireless transceiver element wirelessly outputting the wireless control signal and wirelessly receiving the fan information.

12. The fan signal wireless transmission system as claimed in claim 9, wherein each of the fans includes a fan control unit and a fan motor connected to the fan control unit; and the common second wireless signal transceiver module being connected to each of the fan control units and including a second processor and a second wireless transceiver element connected to the second processor.

13. The fan signal wireless transmission system as claimed in claim 9, wherein the first wireless signal transceiver module and the fans are powered via the power terminal of the system board.

14. The fan signal wireless transmission system as claimed in claim 9, wherein the system board and the first wireless signal transceiver module are two independent members, the system board has a first connector, and the first wireless signal transceiver module has a second connector; and the first wireless signal transceiver module being detachably mounted on the system board via connection of the second connector to the first connector.

15. The fan signal wireless transmission system as claimed in claim 9, wherein the first wireless signal transceiver module is fixedly mounted on the system board.

16. The fan signal wireless transmission system as claimed in claim 9, wherein the first and the second wireless signal transceiver module are selected from the group consisting of infrared modules, radio-frequency (RF) modules, Bluetooth modules, ZigBee modules, near-field communication (NFC) modules, WiFi modules, ultrasonic modules, radio-frequency identification (RFID) modules and 5G modules.
